(19) United States
(12) Patent Application Publication
(10) Pub. No.: US 2012/0074284 A1
(43) Pub. Date: Mar. 29, 2012

(54) Flexible Support Structure

(75) Inventor: Wen-Hung Huang, Taipei County (TW)

(73) Assignee: Hannspree Inc., Taipei City (TW)

(21) Appl. No.: 12/948,052

(22) Filed: Nov. 17, 2010

(30) Foreign Application Priority Data
Sep. 27, 2010 (TW) 099132685

(51) Int. Cl. H05K 7/14; H01F 7/02

(52) U.S. Cl. 248/274.1

(57) ABSTRACT

The present disclosure discloses a flexible support structure, which is applied to a portable electronic device and comprises two support members having flexibility and respectively installed on two sides of the portable electronic device, wherein each support member has a pivotal end whereby the support member is pivotally coupled to the side of the portable electronic device, and wherein the two support members can be deformed to have appropriate shapes to keep the portable electronic device standing up or clamp the portable electronic device onto an object.

### BACKGROUND OF THE INVENTION

1. Field of the Invention

The present invention relates to a flexible support structure, which is applied to a portable electronic device to support a portable electronic device or to clamp the portable electronic device onto a table or the thigh/arm of a user.

2. Description of the Related Art

The manufacturers have persistently proposed various new styles of portable electronic devices (such as tablet PC) that are slim and lightweight to improve portability and operation. For application convenience, the related manufacturers have also persistently developed various accessories for portable electronic devices.

US patents of publication Nos. 2006/0166720A1, 2008/0087789A1 and 2009/0095854A1 respectively disclosed auxiliary devices, which are optional, to support the portable electronic devices standing up in accordance with the users' demands. However, there is inconvenience that the extra accessory (meaning the auxiliary devices) must be separately stored and carried when the auxiliary device is detached from the portable electronic device.

### SUMMARY OF THE INVENTION

The primary objective of the present invention is to provide a flexible support structure to support a portable electronic device or clamp the portable electronic device onto an object, such as a table or the thigh/arm of the user, wherein two side bars of the flexible support structure not in use can be retrieved and attached to the side of the portable electronic device.

The present disclosure provides a flexible support structure, which is applied to a portable electronic device and comprises two flexible support members respectively oppositely installed on two opposite sides of the portable electronic device, wherein each flexible support member having a pivotal end whereby the both support members are pivotally coupled to the both sides of the portable electronic device, wherein each flexible support member having a pivotal end is pivotally coupled to the side of the portable electronic device, and the flexible support member can be deformed to appropriate shapes so as to support the portable electronic device.

In one embodiment, the flexible support member is a flexible wire.

In one embodiment, the flexible support member is a flexible plate.

In one embodiment, the flexible support member further comprises a flexible tube wrapping the flexible support member

In one embodiment, the flexible support member further comprises a fixing element arranged opposite to the pivotal end and detachably coupled to the edge of the portable electronic device.

In one embodiment, the flexible support member further comprises at least one fixing element detachably coupled to the edge of the portable electronic device.

In one embodiment, the side of the portable electronic device further comprises a recess for detachably fitting the fixing element.

In one embodiment, the fixing element is a protrusion.

In one embodiment, the fixing element is a magnet.

In one embodiment, the portable electronic device is a tablet PC, a portable computer, a music playing device, or a video playing device.

### BRIEF DESCRIPTION OF THE DRAWINGS

FIG. 1 is a perspective view schematically showing a portable electronic device with a flexible support structure according to one embodiment of the present disclosure;

FIG. 2 is a perspective view schematically showing a portion of a portable electronic device with a flexible support structure according to one embodiment of the present disclosure;

FIG. 3 is a front view of a portable electronic device with a flexible support structure according to one embodiment of the present disclosure;

FIG. 4 is a perspective view schematically showing a portion of a flexible support structure according to one embodiment of the present disclosure;

FIG. 5 is a sectional view along Line A-A in FIG. 4 according to one embodiment of the present disclosure;

FIG. 6 is a sectional view along Line A-A in FIG. 4 according to another embodiment of the present disclosure;

FIG. 7A is a diagram schematically showing a portable electronic device with a flexible support structure according to one embodiment of the present disclosure;

FIG. 7B is a diagram schematically showing a portable electronic device with a flexible support structure according to one embodiment of the present disclosure;

FIG. 8A is a diagram schematically showing a portable electronic device with a flexible support structure according to another embodiment of the present disclosure;

FIG. 8B is a side view of the portable electronic device with the flexible support structure shown in FIG. 8A;

FIG. 9A is a diagram schematically showing the application of a portable electronic device with a flexible support structure according to a further embodiment of the present disclosure; and

FIG. 9B is a side view of the portable electronic device with the flexible support structure shown in FIG. 9A.

### DETAILED DESCRIPTION OF THE INVENTION

Below, the embodiments are described in detail to demonstrate the technical contents of the present disclosure.

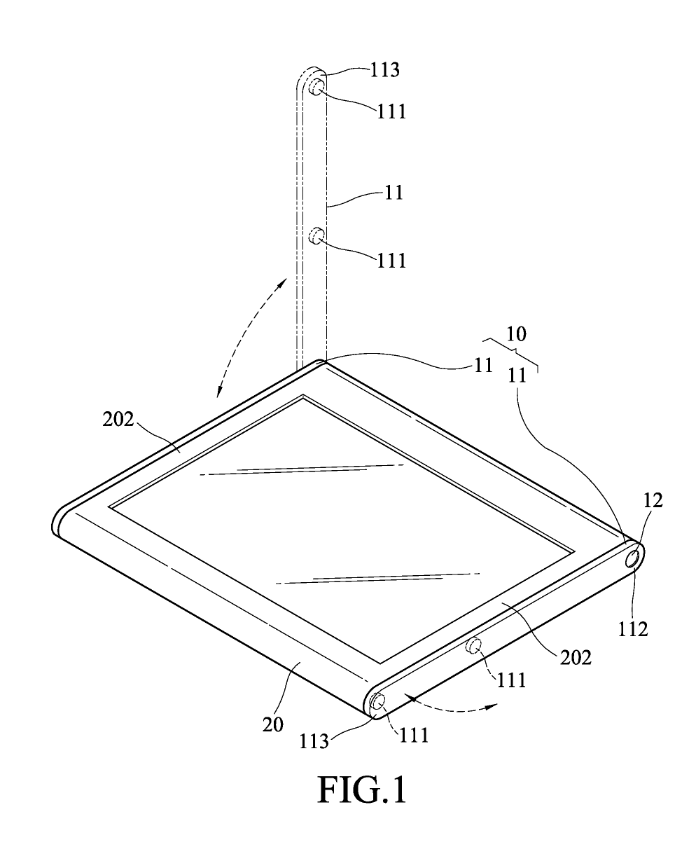

Referring to FIG. 1, a perspective view schematically shows a portable electronic device 20 with a flexible support structure 10 according to one embodiment of the present disclosure. The present disclosure proposes a flexible support structure 10 to support a portable electronic device 20. The flexible support structure 10 comprises two support members symmetrically arranged on two opposite sides 202 of the portable electronic device 20. The present disclosure does not restrict that the flexible support member 11 should be arranged symmetrically on the portable electronic device 20 but allows the flexible support member 11 to be arbitrarily arranged on the portable electronic device 20. The flexible support member 11 can be deformed and maintain the post-deformation shape to attain various positions, whereby the flexible support structure 10 can support the portable electronic device 20 to stand up or clamp the portable electronic device 20 onto the thigh or arm of the user. In the present disclosure, the portable electronic device 20 may be a tablet PC, a portable computer, a music playing device, or a video playing device.

In this embodiment, the two flexible support members 11 are respectively arranged on the left and right side 202 of the portable electronic device 20. Each flexible support member 11 has a pivotal end 112 pivotally coupled to the side 202 of the portable electronic device 20 and closely contacting the side 202. Each flexible support member 11 also has a free end 113 opposite to the pivotal end 112 and detachably coupled to the side 202 of the portable electronic device 20, as shown in FIG. 1.

Referring to FIG. 1, each flexible support member 11 is pivotally coupled to the side 202 of the portable electronic device 20 via a pivotal element 12, whereby the flexible support member 11 can rotate with respect to the portable electronic device 20 with the pivotal element 212 being the rotation axis. In FIG. 1, shows that the flexible support member 11 can rotates upward by an angle of 90 degrees to a vertical position. It should be mentioned particularly that the flexible support member 11 can maintain the curved posture after deformation. Therefore, the user can rotate and/or bend the flexible support member 11 to have postures required by an application.

To enable the flexible support members 11 to fixedly attach to the side 202 of the portable electronic device 20, each support member 11 has a fixing element 111 opposite to the pivotal end 112. The fixing element 111 can detachably connect with the side 202 of the portable electronic device 20.

In another embodiment, each flexible support member 11 has at least one fixing element 111 arranged between the pivotal end 112 and the free end 113 and detachably coupled to the side 202 of the portable electronic device 20.

Referring to FIG. 1 and FIG. 4, FIG. 4 is a perspective view schematically showing a portion of a flexible support structure 10 according to one embodiment of the present disclosure. In this embodiment, the fixing element 111 is a protrusion protruding toward the side 202 of the portable electronic device 20.

In another embodiment, the fixing element 111 is a magnet. The flexible support member 11 is magnetic attached to the side 202 of the portable electronic device 20 via the magnetic force of the fixing element 111, not shown.

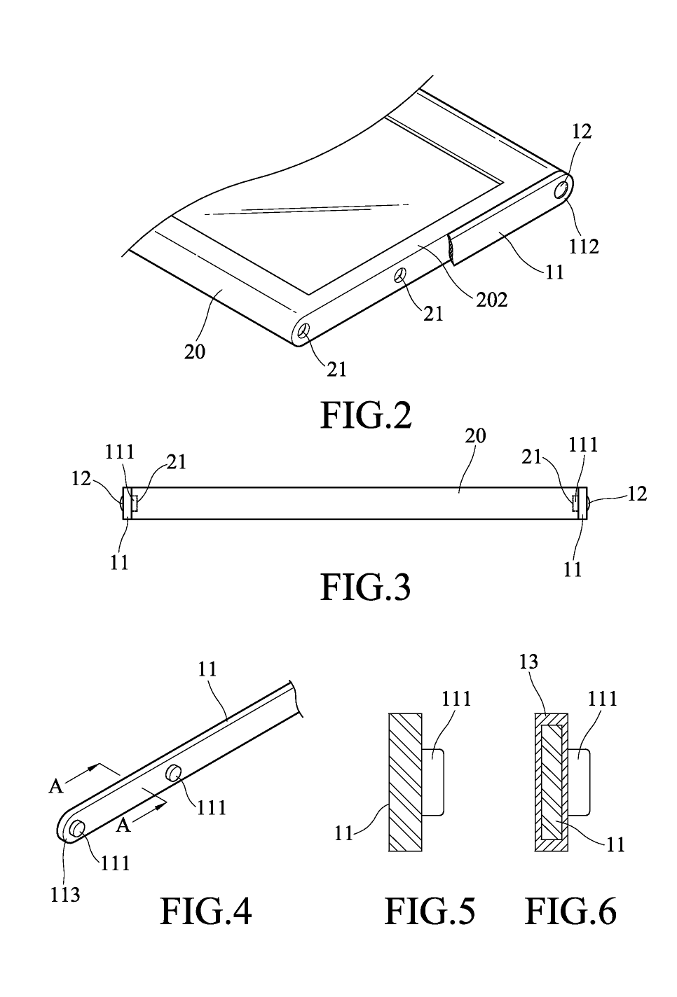

Referring to FIG. 2 and FIG. 3, FIG. 3 is a front view of a portable electronic device 20 with a flexible support structure 10 according to one embodiment of the present disclosure. In this embodiment, the side 202 of the portable electronic device 20 has at least one recess 21 to receive the fixing element 111. The flexible support member 11 can be secured in position via the engagement of the fixing element 111 and the recess 21.

Referring to FIG. 4 and FIG. 5, FIG. 5 is a sectional view along Line A-A in FIG. 4 according to one embodiment of the present disclosure. In this embodiment, the flexible support member 11 is a flexible wire or a flexible plate, such as a steel wire or a steel plate.

Referring to FIG. 6, a sectional view along Line A-A in FIG. 4 according to another embodiment of the present disclosure. In this embodiment, the flexible support member 11 is sleeved by a flexible tube 13 made of plastic or rubber materials.

In summary, the present disclosure proposes a flexible support structure 10 comprising two flexible support members 11 respectively installed on two sides 202 of a portable electronic device 20. When not in use, the two flexible support members 11 respectively closely attach to the left and right sides 202 of the portable electronic device 20. Each flexible support member 11 rotates with respect to the portable electronic device 20 via the pivotal element 12 and bent arbitrarily with respect to the portable electronic device 20. Therefore, the flexible support members 11 can present various postures to support the portable electronic device 20 to stand up or clamp the portable electronic device 20 onto an object or on user's thigh/arm.

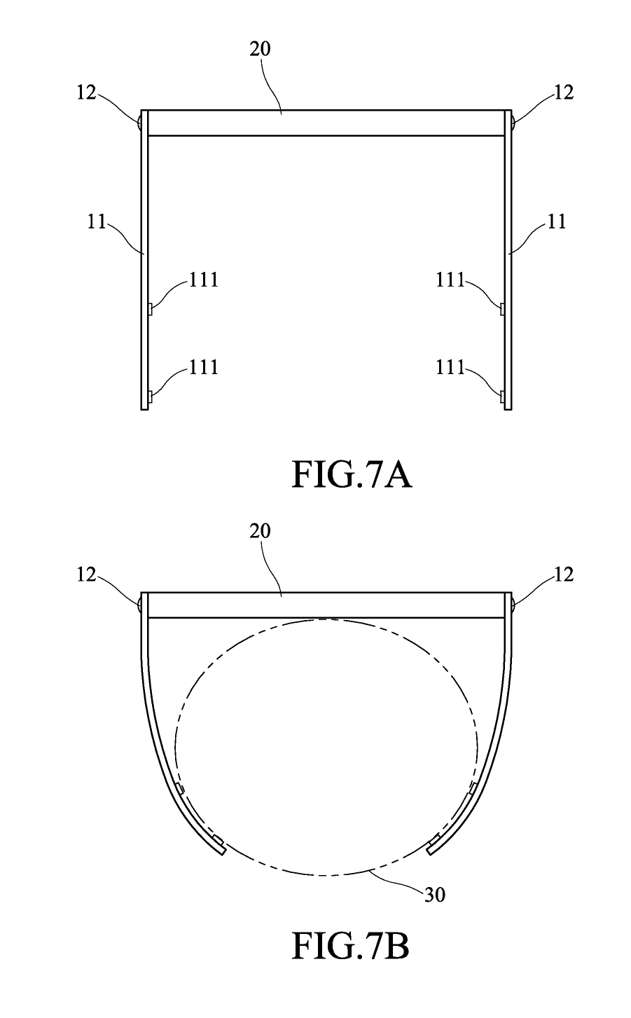

Referring to FIG. 7A and FIG. 7B, diagrams schematically shows a first application of a portable electronic device 20 with a flexible support structure 10 according to one embodiment of the present disclosure. When intending to clamp the portable electronic device 20 to an object or the thigh of the user, first the user rotates the two flexible support members 11 downward, as shown in FIG. 7A. Next, the two flexible support members 11 are respectively placed on two sides of the object 30 and bent toward the object 30. Thereby, the two flexible support members 11 clamp the portable electronic device 20 onto the object 30 to convenience the operation, as shown in FIG. 7B.

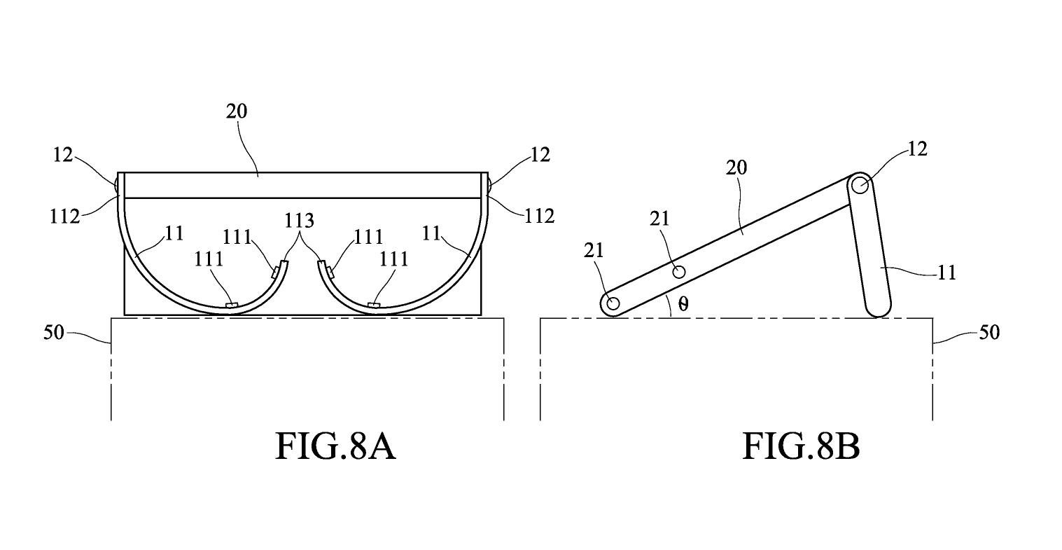

Referring to FIG. 8A and FIG. 8B, it is the second application of the present disclosure. FIG. 8A is a diagram schematically showing a portable electronic device 20 with a flexible support structure 10 according to another embodiment of the present disclosure. FIG. 8B is a side view of the portable electronic device 20 with the flexible support structure 10 shown in FIG. 8A. When intending to maintain the portable electronic device 20 at a specified tilt angle, the user first rotates the two flexible support members 11 downward. Next, the two flexible support members 11 are bent toward to the center of the lower face of the portable electronic device 20 to form two arcs, as shown in FIG. 8A. Thereby, the two pivotal ends 112 of the flexible support members 11 raise the top end of the portable electronic device 20. Thus, the portable electronic device 20 placing on a table 50 is maintained at an appropriate tilt angle; depending on user's preference, the tilt angle can be adjusted through the pivotal element 12.

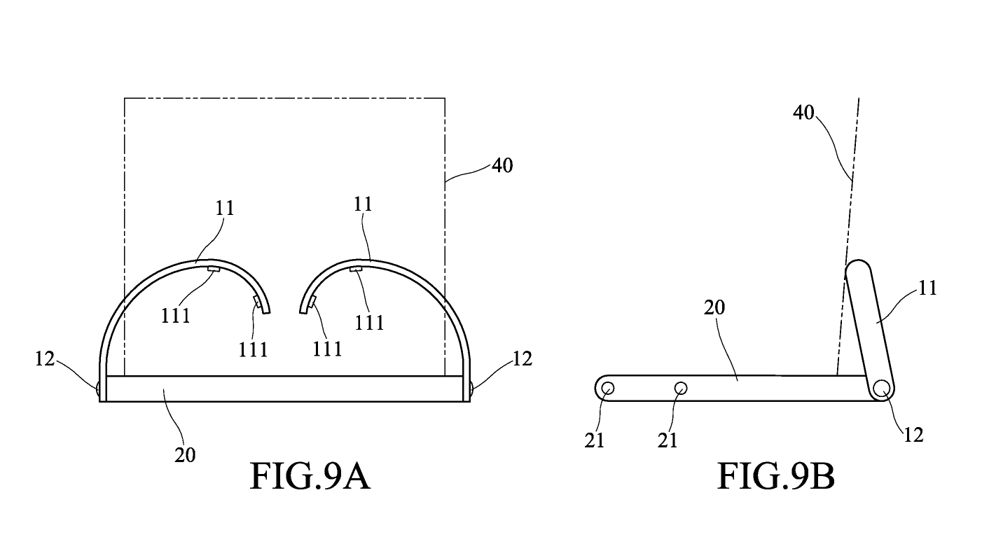

Refer to FIG. 9A and FIG. 9B for a third application of the present disclosure. FIG. 9A is a diagram schematically showing a portable electronic device 20 with a flexible support structure 10 according to a further embodiment of the present disclosure. FIG. 9B is a side view of the portable electronic device 20 with the flexible support structure 10 shown in FIG. 9A. The user rotates the two flexible support members 11 upward, when intending to support a piece of paper 40 or a book to stand up. Then the two flexible support members 11 are bent toward to the center of the upper face of the portable electronic device 20 to form two arcs, as shown in FIG. 9A. Thus, the two flexible support members 11 are deformed to have a rack-like structure to support the paper 40 or book standing up.

In conclusion, the present disclosure proposes a flexible support structure 10 to support a portable electronic device 20 standing up or clamp the portable electronic device 20 onto an object. When not in use, the two flexible support members 11 of the flexible support structure 10 can be retrieved and attached to the side 202 of the portable electronic device 20, not affecting the appearance nor occupying any space.

The embodiments described above are only to exemplify the present disclosure but not to limit the scope of the present disclosure. Any equivalent modification or variation according to the spirit of the present disclosure is to be also included within the scope of the present disclosure.

What is claimed is:

1. A flexible support structure for a portable electronic device, comprising:
two flexible support members respectively oppositely installed on two sides of the portable electronic device, wherein each flexible support member having a pivotal end is pivotally coupled to the side of the portable electronic device, and the flexible support member can be deformed to appropriate shapes so as to support the portable electronic device.

2. The flexible support structure according to claim 1, wherein the flexible support member is a flexible wire.

3. The flexible support structure according to claim 1, wherein the flexible support member is a flexible plate.

4. The flexible support structure according to claim 1, further comprising a flexible tube wrapping the flexible support member.

5. The flexible support structure according to claim 1, wherein the flexible support member further comprises a fixing element arranged opposite to the pivotal end and detachably coupled to the side of the portable electronic device.

6. The flexible support structure according to claim 1, wherein the flexible support member further comprises at least one fixing element detachably coupled to the side of the portable electronic device.

7. The flexible support structure according to claim 5, wherein the side of the portable electronic device further comprises a recess for detachably fitting the fixing element.

8. The flexible support structure according to claim 6, wherein the side of the portable electronic device further comprises a recess for detachably fitting the fixing element.

9. The flexible support structure according to claim 5, wherein the fixing element is a protrusion.

10. The flexible support structure according to claim 6, wherein the fixing element is a protrusion.

11. The flexible support structure according to claim 5, wherein the fixing element is a magnet.

12. The flexible support structure according to claim 6, wherein the fixing element is a magnet.

13. The flexible support structure according to claim 1, wherein the portable electronic device is a tablet PC, a portable computer, a music playing device, or a video playing device.
